(19) United States
(12) Patent Application Publication
(10) Pub. No.: US 2025/0277679 A1
(43) Pub. Date: Sep. 4, 2025

(54) INDUCTIVE PROXIMITY SENSOR WITH TEMPERATURE STABILIZATION

(71) Applicant: OPTOSYS SA, Corminboeuf (CH)

(72) Inventor: Laurent GENILLOUD, Romont (CH)

(21) Appl. No.: 19/065,003

(22) Filed: Feb. 27, 2025

(30) Foreign Application Priority Data
Feb. 29, 2024 (EP) 24160712.6

(51) Int. Cl. G01D 5/20; G01D 18/00; G01K 1/02

(52) U.S. Cl. CPC G01D 5/20; G01D 18/00; G01K 1/026

(57) ABSTRACT

An inductive proximity sensor for detecting the proximity of an external object, includes a sensing part (10) including a sensor coil (12) for generating a magnetic field, a first temperature sensor (14) arranged at the sensing part and configured to provide a first temperature signal, at least a second temperature sensor (26) arranged at a distance from the first temperature sensor and configured to provide a second temperature signal, and an evaluation part (20). The latter is configured to provide a primary detection signal based on detected variations of the magnetic field caused by the external object and to correct the primary detection signal based on at least the first and second temperature signals in order to provide an output detection signal which is related to the proximity of the external object and compensated for a temperature change.

### FIELD OF THE INVENTION

The present invention relates to an inductive proximity sensor for detecting the proximity of an external object, comprising a sensing part with a sensor coil for generating a magnetic field.

### BACKGROUND OF THE INVENTION

Such sensors are e.g. configured such that the coil is part of an electrical resonant circuit for generating an alternating magnetic field, which is emitted via the coil. If a metallic or magnetic object enters the effective range of the magnetic field, eddy currents are generated in the object. This alters the magnetic field, and the sensor is able to detect this alteration.

An inductive proximity sensor may be sensitive to the ambient temperature, such that the detection of an object is not reliable anymore. In order to reduce this sensitivity, a temperature compensation may be implemented, see e.g. the patent U.S. Pat. No. 4,509,023 of the same applicant.

The known measures for temperature compensation only work reliably if the sensor is at temperature equilibrium. However, they fail when the sensor warms up after power is switched on or after a sudden ambient temperature modification. In these cases, a drift in the output signal of the sensor can be seen which is not effectively corrected by the temperature compensation provided.

### SUMMARY OF THE INVENTION

It is an aim of the present invention to provide for an inductive proximity sensor which generates a reliable output signal even when it is not at temperature equilibrium.

This aim is achieved by an inductive proximity sensor as defined in claim 1. The provision of a first and second temperature sensor allows the evaluation part to correct the primary detection signal in order to provide an output detection signal which is related to the proximity of the object and compensated for a temperature change.

Thus, the proximity sensor may detect a temperature gradient which arises within the sensor when it warms up after switching on and/or when it is subjected to a sudden ambient temperature modification and correct the output signal accordingly.

Preferably, the second temperature sensor may have a minimum distance to the first temperature sensor of at least half of the maximum diameter of the housing of the inductive proximity sensor. More preferably, said minimum distance is at least the maximum diameter of the housing.

The further claims specify preferred embodiments of the inductive proximity sensor and a method of testing such a sensor.

In one embodiment, correction is done by additionally taking the distance of the object to the proximity sensor into account.

### BRIEF DESCRIPTION OF DRAWINGS

The invention is explained in the following by means of exemplary embodiments with reference to Figures. In the drawings:

FIG. 1 shows an embodiment of the proximity sensor according to the invention in a schematic way;

FIG. 2 shows an example of the output signal PD of the proximity sensor, when the temperature gradient within the proximity sensor is not taken into account;

FIG. 3 shows an example of the signals provided by two temperature sensors of the proximity sensor;

FIG. 4 shows the difference of the two signals shown in FIG. 3;

FIG. 5 shows an example of the primary output signal of the proximity sensor, which is uncorrected with regard to temperature variations, and of the wanted signal;

FIG. 6 shows an example of the correction factor in relation to the temperature difference measured;

FIG. 7 shows an example of the uncorrected primary output signal, and the corrected output signal;

FIG. 8 shows an example of the linear coefficient of the correction factor in relation to the uncorrected primary output signal; and

FIG. 9 shows an example of the offset coefficient of the correction factor in relation to the uncorrected primary output signal.

### DETAILED DESCRIPTION OF THE PREFERRED EMBODIMENTS

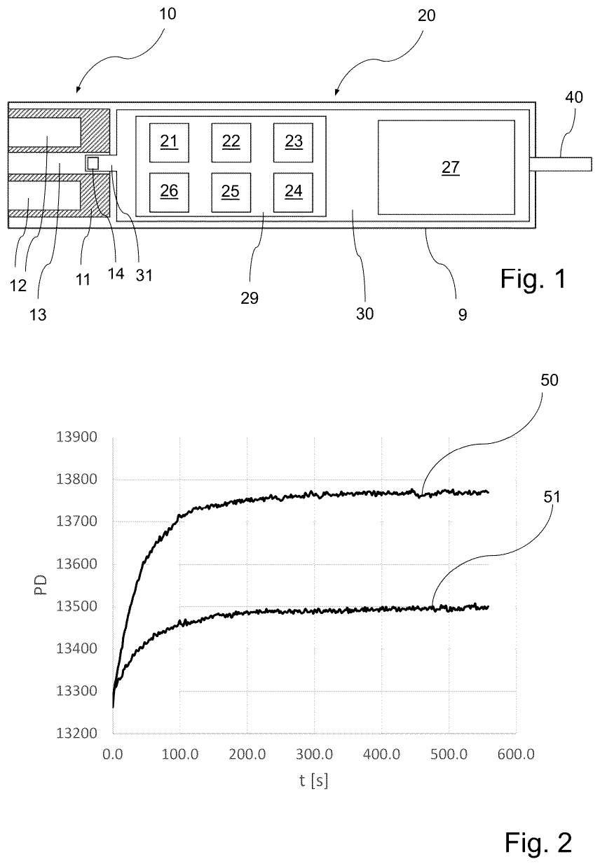

FIG. 1 shows an embodiment of an inductive proximity sensor including a sensing part 10 and an evaluation part 20 arranged in a housing 9.

The sensing part 10 includes a carrier 11 on which a sensing coil 12 is arranged. The carrier 11 includes an opening 13 forming a recess and is e.g. made of ferrite or another material for shaping, in particular focusing the magnetic field emitted by the inductive proximity sensor. In the present embodiment, the carrier 11 is ring-shaped so that opening 13 is part of a through-opening.

At the sensing part 10, there is provided a first temperature sensor 14 for sensing a first temperature which is related to the temperature of the sensing coil 12 and/or the carrier 11. The first temperature sensor 14 is arranged in the opening 13 of the carrier 11. By positioning the first temperature sensor 14 at the sensing part 10, it is possible to gain information on the actual temperature of the coil 12 and/or the carrier 11 to counteract a possible drift in the output signal of the proximity sensor due to temperature changes.

The evaluation part 20 includes a circuitry with the following elements:
an oscillator 21 which together with the sensing coil 12 is configured to form a resonant circuit, in particular a LC-circuit;
a signal shaping component 22 for receiving a signal from the resonant circuit and for shaping the signal; preferably the signal shaping component 22 is configured to give a response that is monotonically increasing when the target distance, i.e. the distance between the proximity sensor and an object to be detected, is increasing;
an output amplifier 23 which amplifies the signal received from the signal shaping component 22; preferably the output amplifier 23 is configured to amplify the signal so that it can be then digitalized;
a digital part 24 configured to receive signals from the output amplifier 24, from the first temperature sensor 14 and from the second temperature sensor 26, to digitalize those signals and compute a corrected signal;
a memory 25 for storing information used by the digital part 24;
a second temperature sensor 26 for sensing a second temperature at a second location;
additional electronic components 27.

The components 21-26 may be part of an ASIC 29 (“application-specific integrated circuit”). It is conceivable, that some of the components 21-26 are separate components, e.g. the second temperature sensor 26 may be a component separate from the ASIC 29. The digital part 24 and/or memory 25 may part of a microcontroller for performing a digitalization of the input signals and a computation of the corrected signal.

The components 21-27 are arranged on a circuit board 30, in particular a printed circuit board. In the present embodiment, the circuit board 30 includes a protrusion 31 which extends into the opening 13 and on which the first temperature sensor 14 is arranged.

The proximity sensor includes a transfer part for transferring signals to an external device, e.g. a cable 40 extending from the housing 9 as indicated in FIG. 1 and/or a connector arranged on the housing 9.

In use, an alternating magnetic field is produced by the sensing coil 12 and the oscillator 21 and emitted through the front part of the housing 9. The presence of an object can alter this field and the sensor is able to detect this alteration. The first temperature sensor 14 and second temperature sensor 26 sense the temperature at different locations, which allow the determination of a correction signal as explained hereinafter.

In the diagram shown in FIG. 2, the abscissa represents time in units of seconds, and the ordinate corresponds to the output signal PD of the proximity sensor in arbitrary units in case that the proximity sensor is switched on and no correction with regard to the temperature gradient within the proximity sensor is taken into account. However, the proximity sensor is configured to compensate the signal with regard to the temperature once it has been warmed up and is in thermal equilibrium. To this end, information on a correction for temperature compensation may be stored in the memory 25, e.g. in form of a look-up table that provides a value for a correction parameter for various temperatures. Based on the temperature measured e.g. by the temperature sensor 26, the corresponding correction parameter in the look-up table is determined and used by the digital part 24 to determine a correction in the signal.

Said information on a correction for a proximity sensor of a specific kind may e.g. be obtained from investigating a sample of one or more proximity sensors of the same specific kind (i.e. same components and same dimensions). A proximity sensor of the sample is exposed to different temperatures and its output signal is captured as a standard target is placed at a specific distance in front of the proximity sensor. Subsequently, correction parameters are determined such that the variation of the output signal due to the temperature changes is reduced, preferably minimized. The same correction parameters may be used for each proximity sensor of the same kind.

In FIG. 2, curve 50 is the output signal PD of the proximity sensor when based on the temperature measured by the first temperature sensor 14. Curve 51 is the output signal PD of the proximity sensor when based on the temperature measured by the second temperature sensor 26. As can been seen, curves 50 and 51 fluctuate around a plateau value after a certain time. However, shortly after powering up the proximity sensor, curves 50 and 51 increase sharply.

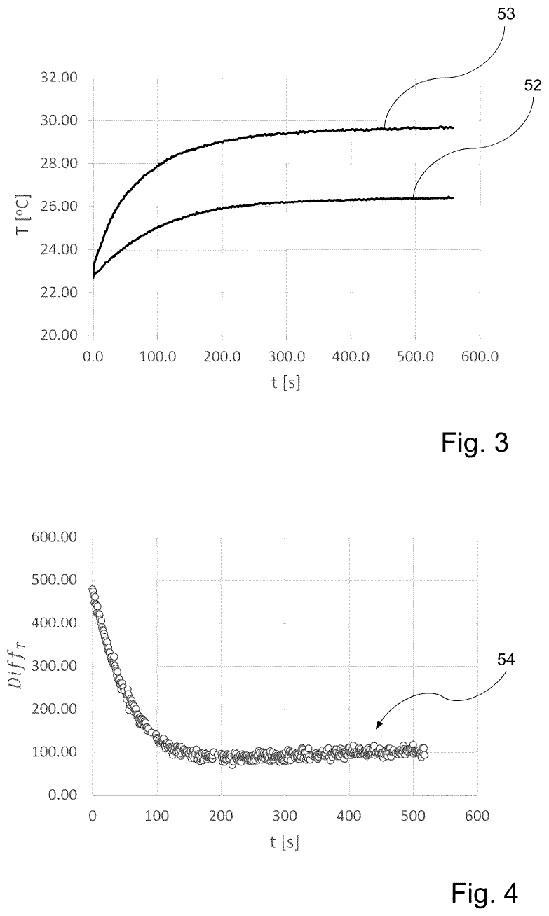

In the diagram shown in FIG. 3, the abscissa represents time t in units of seconds, and the ordinate corresponds to the temperature T in units of degrees Celsius measured when the proximity sensor is switched on. Curve 52 is an example of the time course of the first temperature T₁ measured by the first temperature sensor 14. Curve 53 is an example of the time course of the second temperature T₂ measured by the second temperature sensor 26. As can been seen, curves 52 and 53 fluctuate around a plateau value after a certain time, i.e. after the warm-up phase. However, in the beginning when powering up the proximity sensor, curves 52 and 53 increase rapidly.

The temperature difference between the two signals provided the temperature sensors 14 and 26 is defined as:

$${Diff}_{T} = {T}_{1} - {T}_{2}$$

In the diagram shown in FIG. 4, the abscissa represents time in units of seconds, and the ordinate corresponds to the temperature in arbitrary units. Dots 54 represents the temperature difference Diff_{T} of the two curves 52 and 53 in FIG. 3. Again, it can be seen that after powering up the proximity sensor at t=0, the temperature difference Diff_{T} changes considerably and tends to a constant value after a certain time period.

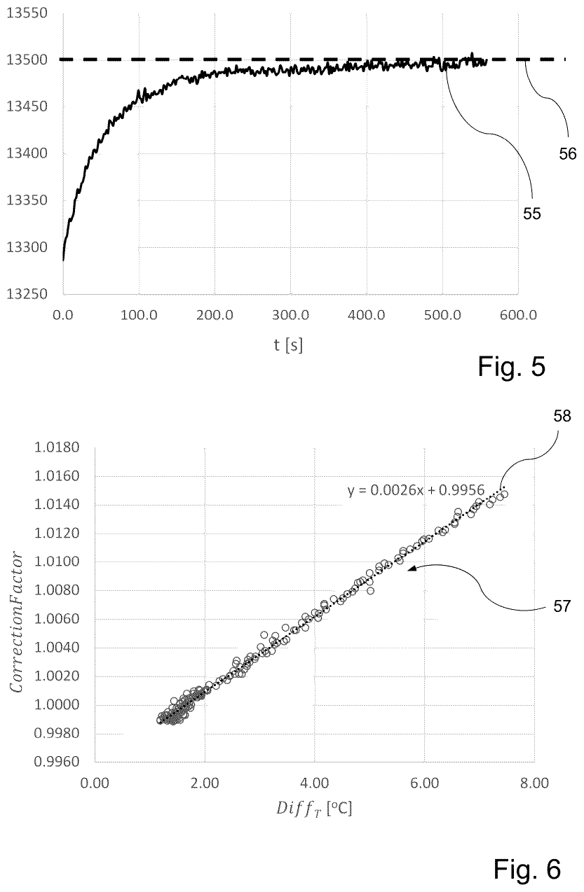

An ideal response of the proximity sensor would be represented by a static output signal independent of the temperature variations within time. Said output signal is in the following denoted by ProcessData_{target} and is indicated in the example of FIG. 5 by the dashed level line 56, wherein the abscissa represents time in units of seconds and the ordinate corresponds to the signal of the proximity sensor PD in arbitrary units.

A correction factor can be defined using the following formula:

$${CorrectionFactor}_{meas} = \frac{{ProcessData}_{target}}{{ProcessData}_{NC}}$$

where ProcessData_{NC} is the primary output signal of the proximity sensor, i.e. without correction of sudden temperature variations. A correction for gradual temperature changes, which allows the proximity sensor to reach a thermal equilibrium, may be provided. For instance, ProcessData_{NC} may be provided by adjusting an input signal in dependence on the temperature measured by the second temperature sensor 26. In FIG. 5 curve 55 shows an example of the primary output signal ProcessData_{NC}.

It has been found that the correction factor CorrectionFactorₘₑₐₛ varies essentially in a linear way with respect to the temperature difference measured Diff_{T}. As an example, FIG. 6 shows different dots 57 corresponding to values measured, wherein the abscissa represents the variable Diff_{T} in units of degrees Celsius, and the ordinate corresponds to the correction factor in arbitrary units. Out of the measured data the two parameters of a linear regression, the linear coefficient (i.e. proportionality factor) Lin_{DiffT} and the offset coefficient (i.e. intercept term) Off_{DiffT}, can be computed, which allows the determination of the correction factor by the following equation 1:

$$Correc {tionFactor}_{Comp} = {Lin}_{DiffT} \cdot {Diff}_{T} + {Off}_{DiffT}$$

Line 58 in FIG. 6 indicates the regression line for the data indicated by dots 57.

The parameters Lin_{DiffT} and the intercept term Off_{DiffT} can be determined for a specific type of proximity sensor. Based on the equation 1 above and the temperature difference Diff_{T} measured by the temperature sensors 14, 26 in time, the correction factor CorrectionFactor_{comp} as a function of time can be determined. Finally, the corrected output signal of the proximity sensor ProcessData_{corr} is determined by means of the following equation 2:

$${ProcessData}_{Corr} = {ProcessData}_{NC} \cdot {CorrectionFactor}_{Comp}$$

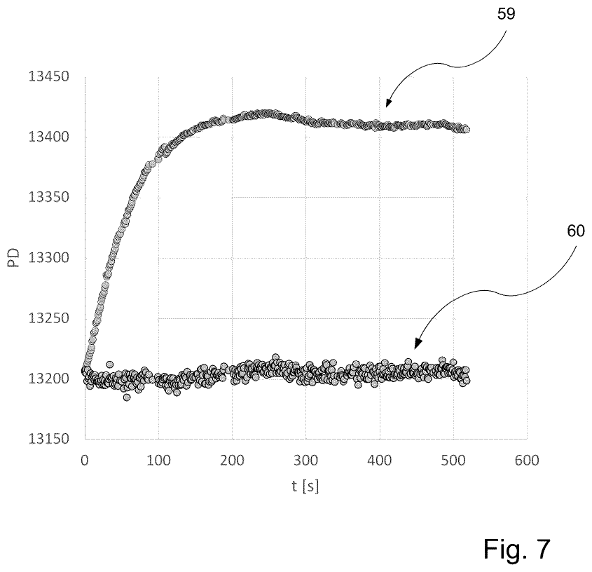

FIG. 7 shows an example of data, wherein the abscissa represents time in units of seconds, and the ordinate corresponds to the signal output in arbitrary units. The dots 59 correspond to the uncorrected data ProcessData_{NC} and the dots 60 represent the corrected data ProcessData_{corr}. As can be seen, variations of the temperature which appear in the proximity sensor after switching it on at t=0 are substantially balanced out, so that the corrected data ProcessData_{corr} are substantially constant.

As explained so far, the correction factor is considered to be a function of the temperature difference:

$${CorrectionFactor}_{Comp} = f ( {Diff}_{T} )$$

In a further embodiment the actual target distance Sᵣ, i.e. the distance between the proximity sensor and the object, can be in addition taken into account to determine the correction factor. The relation between the sensor output and the damping factor implies that the correction factor may be a function of the target distance:

$${CorrectionFactor}_{Comp} = f ( {Diff}_{T} , {S}_{r} )$$

As the target distance Sᵣ is related to the primary output of the proximity sensor ProcessData_{NC} this implies that the correction factor is a function of ProcessData_{NC}

$${CorrectionFactor}_{Comp} = f ( {Diff}_{T} , {ProcessData}_{NC} )$$

To determine this function for a specific proximity sensor, a specific target (“test object”) is placed at a first distance Sᵣ from the proximity sensor, the latter is switched on and the data for ProcessData_{NC} and Diff_{T} are collected. Based on these data the two parameters Lin_{DiffT} and Off_{DiffT} of the linear regression are determined. This procedure is repeated for several target distances Sᵣ.

It has been found that each of the two parameters Lin_{DiffT} and Off_{DiffT} varies essentially in a linear way with respect to the primary output signal ProcessData_{NC}.

In one example the following values are obtained:

| Target distance | ProcessData_{NC} | | |
|---|---|---|---|
| [mm] | (arbitrary units) | Lin_Diff_{T} | Off_Diff_{T} |
| 20 | 13200 | 2.594E−03 | 0.981 |
| 15 | 12400 | 2.205E−03 | 0.982 |
| 10 | 10000 | 1.512E−03 | 0.988 |
| 8 | 8240 | 9.517E−04 | 0.993 |
| 5 | 5394 | 1.122E−04 | 1.000 |

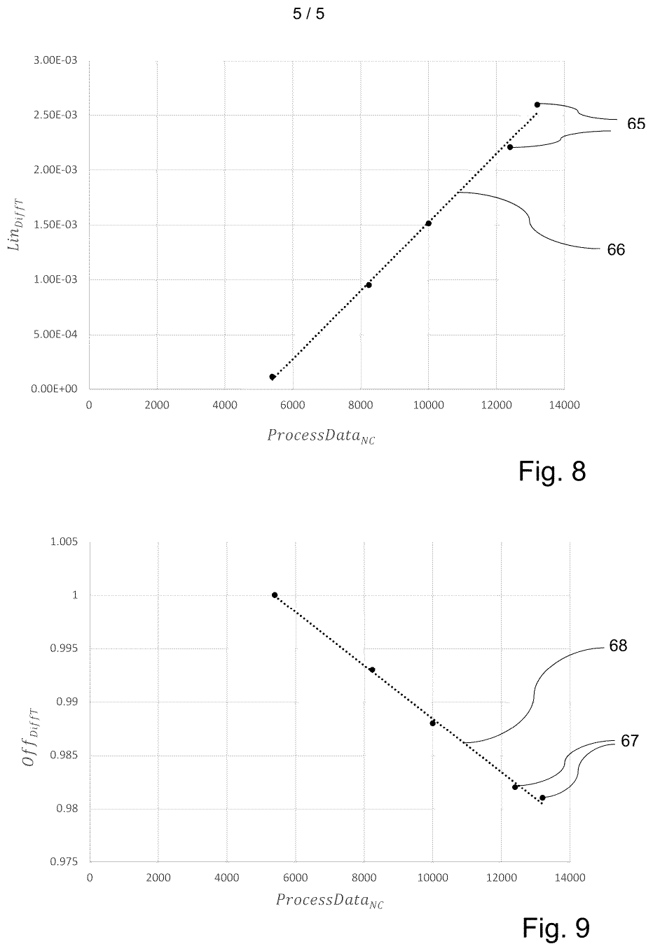

These data are shown in FIGS. 8 and 9 by dots 65 and dots 67, respectively, wherein the abscissa represents the primary output of the proximity sensor ProcessData_{NC} in arbitrary units. In FIG. 8 the ordinate corresponds to parameter Lin_{DiffT} in arbitrary units and in FIG. 9 it corresponds to the parameter Off_Diff_{T} in arbitrary units. As can be seen, the values 65 and 67, respectively are arranged essentially along a line.

Thus, out of the measured data for Lin_{DiffT} the two parameters of a linear regression, the linear coefficient Lin_Lin_Diff_{T} and the offset coefficient Off_Lin_Diff_{T}, can be computed and out of the measured data for Off_Diff_{T} the two parameters of a linear regression, the linear coefficient Lin_Off_Diff_{T} and the offset coefficient Off_Off_Diff_{T}, can be computed.

Once these four parameters are determined, the values for Lin_Diff_{T} and Off_Diff_{T} can be determined for a specific value of ProcessData_{NC} measured. Applying equations 1 and 2 above the CorrectionFactor_{comp} and finally the corrected ProcessData_{corr} can be determined for a specific value of Diff_{T} measured.

When producing a particular type of proximity sensor, a test object is placed within the operating distance and the primary output signal of the sensor, i.e. without being compensated for a sudden temperature change, is compared with the wanted signal e.g. during the warm-up phase of the sensor (see FIG. 5). This allows the determination of the correction parameters, such as Lin_{DiffT} and Off_{DiffT} and/or Lin_Lin_Diff_{T}, Off_Lin_Diff_{T}. Lin_Off_Diff_{T} and Off_Off_Diff_{T}. If required, the comparison is done for several distances between the test object and the proximity sensor.

The correction parameters are then stored in the memory 25 of the proximity sensor. The memory 25 may be part of a microcontroller of the proximity sensor. It has been found that for proximity sensors of the same type, the same correction parameters can be applied and stored in the respective memory 25.

If a quality test is performed during the fabrication of a series of proximity sensors of a specific type a test object is placed in front of a proximity sensor, the latter is switched on and the output detection signal provided in its warm-up phase is compared with the wanted signal. This test method is time-efficient and thus advantageous with regard to the traditional test procedures applied to proximity sensors having a usual temperature compensation system. Such proximity sensors are first warmed-up before the test can be performed.

The temperature correction measures described herein allows a stabilization of the output of the proximity sensor during the warm-up phase after the sensor has been switched on and/or after a sudden ambient temperature modification. In the particular, the following effects can be counteracted:
Thermal Inertia:
   A proximity sensor includes various components, such a coil and an electronic circuitry, which have thermal inertia, meaning that they take some time to reach thermal equilibrium with the surrounding environment. During the warm-up phase, these components might still be adjusting to the operating temperature, which-without temperature correction measures-would lead to output fluctuations.
Rate of temperature change:
   If the proximity sensor is subject to a rapid change in temperature, the present measures provided for a temperature correction make it possible to effectively counteract the temperature-induced variations. It can be avoided that sudden changes in temperature create temporary discrepancies between the actual sensor output and the wanted output. Such temporary discrepancies appear with proximity sensors having a usual temperature compensation system, which need some time until it catches up with the new temperature conditions.

The temperature correction measures described herein to correct the signal can be applied to various types of proximity inductive sensors, e.g. such which are configured as switches or as sensors for determining the distance to an object when located within the operating distance of the proximity sensor. Said temperature correction measures are particularly beneficial for long distance proximity inductive sensors, which have an operating distance of at least 5 mm.

The operating distance of inductive sensors is the distance at which a target approaching the sensing face triggers a signal change.

From the preceding description, many modifications are available to the skilled person without departing from the scope of the invention, which is defined in the claims.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. An inductive proximity sensor for detecting a proximity of an external object, comprising:
a sensing part including a sensor coil for generating a magnetic field, the sensing part being arranged inside a front portion of a housing;
a first temperature sensor arranged at the sensing part and configured to provide a first temperature signal;
at least a second temperature sensor arranged at a distance from the first temperature sensor and configured to provide a second temperature signal; and
an evaluation part configured to provide a primary detection signal based on detected variations of the magnetic field caused by the external object, wherein the evaluation part is configured to correct the primary detection signal based on at least the first and second temperature signals in order to provide an output detection signal which is related to the proximity of the external object and compensated for a temperature change.

2. The inductive proximity sensor according to claim 1, wherein the sensing part includes a recess in which the first temperature sensor is arranged.

3. The inductive proximity sensor according to claim 1, wherein the sensing part includes a carrier on which the sensing coil is arranged.

4. The inductive proximity sensor according to claim 1, wherein a carrier of the sensing part is ring-shaped to form a recess.

5. The inductive proximity sensor according to claim 1, further including a circuit board which is arranged inside the housing and which includes a protrusion extending into a recess of the sensing part, the first temperature sensor being arranged on the protrusion.

6. The inductive proximity sensor according to claim 1, further including a circuit board which is arranged inside the housing, at least one selected of the group of the first temperature sensor, the second temperature sensor and at least a part of the evaluation part being arranged on the circuit board.

7. The inductive proximity sensor according to claim 1, wherein the second temperature sensor is arranged inside a rearward portion of the housing adjoining the front portion.

8. The inductive proximity sensor according to claim 1, wherein the second temperature sensor is part of an ASIC.

9. The inductive proximity sensor according to claim 1, wherein the second temperature sensor has a minimum distance to the first temperature sensor of at least half of a maximum diameter of the housing.

10. The inductive proximity sensor according to claim 1, wherein the evaluation part is configured to correct the primary detection signal in digital form.

11. The inductive proximity sensor according to claim 1, wherein the evaluation part is configured to provide the output detection signal by applying a correction factor to the primary detection signal, wherein the correction factor is determined as a function of the first and second temperature signals.

12. The inductive proximity sensor according to claim 1, wherein the evaluation part is configured to provide the output detection signal by applying a correction factor to the primary detection signal, wherein the correction factor is determined as a function of the first and second temperature signals and the primary detection signal.

13. The inductive proximity sensor according to claim 1, wherein the evaluation part is configured to provide the output detection signal as digital data or in analogue form of a voltage output or a current output.

14. The inductive proximity sensor according to claim 1, wherein the evaluation part is configured to produce the primary detection signal by adjusting an input signal in dependence on the first temperature signal or on the second temperature signal.

15. The inductive proximity sensor according to claim 1, wherein the evaluation part is arranged in the housing.

16. The inductive proximity sensor according to claim 1, wherein the evaluation part comprises a memory in which first correction parameters are stored, the first correction parameters defining a first linear relationship between a difference between the temperatures determined by the first and second temperature sensors and a correction factor applied to the primary detection signal.

17. The inductive proximity sensor according to claim 1, wherein the evaluation part is configured to correct the primary detection signal as a function of the first and second temperature signals and the primary detection signal in order to provide an output detection signal which is compensated for a temperature change and a change in a distance between the inductive proximity sensor and the external object.

18. The inductive proximity sensor according to claim 1, wherein first correction parameters define a first linear relationship between a difference between the temperatures determined by the first and second temperature sensors and a correction factor applied to the primary detection signal, the first correction parameters including a linear coefficient and a offset coefficient of a linear regression, wherein second correction parameters are stored in a memory of the evaluation part which define at least one of a second linear relationship between the linear coefficient and the primary detection signal and a third linear relationship between the offset coefficient and the primary detection signal.

19. The inductive proximity sensor according to claim 1, which is configured to determine at least one of the
the absence or presence of the external object within an operating distance of the inductive proximity sensor, and
the distance to the external object when located within the operating distance.

20. A method of testing an inductive proximity sensor according to claim 1, wherein a test object to be detected is placed in front of the inductive proximity sensor, the latter is switched on and a output detection signal provided by the inductive proximity sensor in its warm-up phase is compared with a wanted signal.

21. The method according to claim 20, wherein a distance between the test object and the inductive proximity sensor is changed during the warm-up phase of the proximity sensor.
